(19) United States
(12) Patent Application Publication
(10) Pub. No.: US 2023/0051484 A1
(43) Pub. Date: Feb. 16, 2023

(54) EPITAXIAL STRUCTURE AND MANUFACTURING METHOD THEREOF, AND LIGHT-EMITTING DIODE DEVICE

(71) Applicant: CHONGQING KONKA PHOTOELECTRIC TECHNOLOGY RESEARCH INSTITUTE CO., LTD., Chongqing (CN)

(72) Inventors: Pengjun GU, Chongqing (CN); Yongxing LIU, Chongqing (CN)

(21) Appl. No.: 17/971,052

(22) Filed: Oct. 21, 2022

Related U.S. Application Data
(63) Continuation of application No. PCT/CN2021/111783, filed on Aug. 10, 2021.

(51) Int. Cl. H01L 33/06; H01L 33/10; H01L 33/30; H01L 33/00

(52) U.S. Cl. CPC H01L 33/06; H01L 33/10; H01L 33/30; H01L 33/0062

(57) ABSTRACT

An epitaxial structure and a manufacturing method thereof, and a light-emitting diode (LED) device are provided. The epitaxial structure includes an N-type semiconductor layer, a multiple quantum well (MQW) active layer, and a P-type semiconductor layer sequentially stacked in a growth direction. The MQW active layer includes a front MQW active layer and a back MQW active layer sequentially stacked in the growth direction. The front MQW active layer includes at least two groups of first quantum barrier layers and first quantum well layers alternately stacked. The back MQW active layer includes at least two groups of second quantum barrier layers and second quantum well layers alternately stacked. A content of an aluminum (Al) component in each second quantum well layer is gradually increased in the growth direction, and a content of a gallium (Ga) component in each second quantum well layer is gradually decreased in the growth direction.

### CROSS-REFERENCE TO RELATED APPLICATION(S)

This application is a continuation of International Application No. PCT/CN2021/111783, filed Aug. 10, 2021, the entire disclosure of which is hereby incorporated by reference.

### TECHNICAL FIELD

This disclosure relates to the field of semiconductor manufacturing technology, and in particular, to an epitaxial structure and a manufacturing method thereof, and a light-emitting diode (LED) device.

### BACKGROUND

At present, high-brightness aluminum gallium indium phosphorus (AlGaInP) red-light light-emitting diodes (LEDs) have wide applications and are electronic components that directly convert electrical energy into light energy by generating photons through radiative recombination between conduction band electrons (CBEs) and valence band holes in semiconductor materials. Compared with traditional light sources, the high-brightness AlGaInP red-light LEDs have advantages such as high efficiency, energy saving, environmental protection, and longevity, playing an important role in energy conservation, emission reduction, and green development, so as to be recognized as a new generation of green lighting sources in the 21st century.

In the AlGaInP red-light LEDs, effective masses of electrons are less than that of holes, but mobility of electrons are greater than that of holes, such that electrons that are not confined to an active area may be recombined outside the active area to emit lights and generate light sources in other wavebands, which in turn reduces the number of carriers in the active area, decreases recombination probabilities of electrons and holes in the active area, affects internal quantum efficiency of the LEDs, and further affects light-emitting brightness.

Therefore, how to improve the recombination probabilities of the electrons and the holes in the active area to improve the light-emitting brightness is a problem to-be-solved.

### SUMMARY

An epitaxial structure is provided. The epitaxial structure includes an N-type semiconductor layer, a multiple quantum well (MQW) active layer, and a P-type semiconductor layer that are sequentially stacked in a growth direction. The MQW active layer includes a front MQW active layer and a back MQW active layer that are sequentially stacked in the growth direction. The front MQW active layer includes at least two groups of first quantum barrier layers and first quantum well layers that are alternately stacked. The back MQW active layer includes at least two groups of second quantum barrier layers and second quantum well layers that are alternately stacked. A content of an aluminum (Al) component in each of the second quantum well layers is gradually increased in the growth direction, and a content of a gallium (Ga) component in each of the second quantum well layers is gradually decreased in the growth direction.

A manufacturing method of an epitaxial structure is further provided in the disclosure. The manufacturing method of an epitaxial structure includes the following. A gallium arsenide (GaAs) substrate is provided. A GaAs buffer layer, an aluminum gallium arsenide/aluminum arsenide (AlGaAs/AlAs) DBR layer, an N-aluminum indium phosphorus (N—AlInP) confinement layer, an N—AlGaInP waveguide layer, a front MQW active layer, a back MQW active layer, a P—AlGaInP waveguide layer, a P-AlInP confinement layer, and a P—GaP current spreading layer are grown sequentially on the GaAs substrate. The front MQW active layer includes multiple first quantum barrier layers and multiple first quantum well layers that are alternately stacked. The back MQW active layer includes multiple second quantum barrier layers and multiple second quantum well layers that are alternately stacked. A content of an Al component in each of the multiple second quantum well layers is gradually increased in a growth direction, and a content of a Ga component in each of the multiple second quantum well layers is gradually decreased in the growth direction.

An LED device is further provided in the disclosure. The LED device includes an N electrode, a P electrode, and the epitaxial structure of any of the foregoing implementations, where the N electrode is configured to be electrically coupled with the N-type semiconductor layer, and the P electrode is configured to be electrically coupled with the P-type semiconductor layer.

### BRIEF DESCRIPTION OF THE DRAWINGS

FIG. 1 is a schematic diagram illustrating an epitaxial structure of an implementation.

FIG. 2 is a schematic diagram illustrating a front multiple quantum well (MQW) active layer of an implementation.

FIG. 3 is a schematic diagram illustrating a back MQW active layer of an implementation.

FIG. 4 is a schematic structural diagram illustrating a local energy band of an epitaxial structure of an implementation.

Description of reference signs of the accompanying drawings: 100-gallium arsenide (GaAs) substrate, 110-GaAs buffer layer, 120-aluminum gallium arsenide/aluminum arsenide (AlGaAs/AlAs) distributed bragg reflection (DBR) layer, 130-N-aluminum indium phosphorus (N—AlInP) confinement layer, 135-N-type semiconductor layer, 140-N—AlGaInP waveguide layer, 150-front MQW active layer, 155-MQW active layer, 151-first quantum well layer, 152-first quantum barrier layer, 160-back MQW active layer, 161-second quantum well layer, 162-second quantum barrier layer, 170-P—AlGaInP waveguide layer, 175-P-type semiconductor layer, 180-P—AlInP confinement layer, 190-P—GaP current spreading layer.

### DETAILED DESCRIPTION

In order to facilitate understanding of the disclosure, a detailed description will now be given with reference to relevant accompanying drawings. The accompanying drawings illustrate some examples of implementations of the disclosure. However, the disclosure can be implemented in many different forms and is not limited to the implementations described herein. On the contrary, these implementations are provided for a more thorough and comprehensive understanding of the disclosure.

Unless otherwise defined, all technical and scientific terms used herein have the same meaning as commonly understood by those skilled in the art of the disclosure. The terms used herein in the disclosure are for the purpose of describing implementations only and are not intended to limit the disclosure.

In the aluminum gallium indium phosphorus (AlGaInP) red-light LEDs, effective masses of electrons are less than that of holes, but mobility of electrons are greater than that of holes, such that electrons that are not confined to an active area may be recombined outside the active area to emit lights and generate light sources in other wavebands, which in turn reduces the number of carriers in the active area, decreases recombination probabilities of electrons and holes in the active area, affects internal quantum efficiency of the LEDs, and further affects light-emitting brightness.

Therefore, how to improve the recombination probabilities of the electrons and the holes in the active area to improve the light-emitting brightness is a problem to-be-solved.

Based on the above, a solution capable of solving the above technical problem is provided in the disclosure, which will be explained in details in the following implementations.

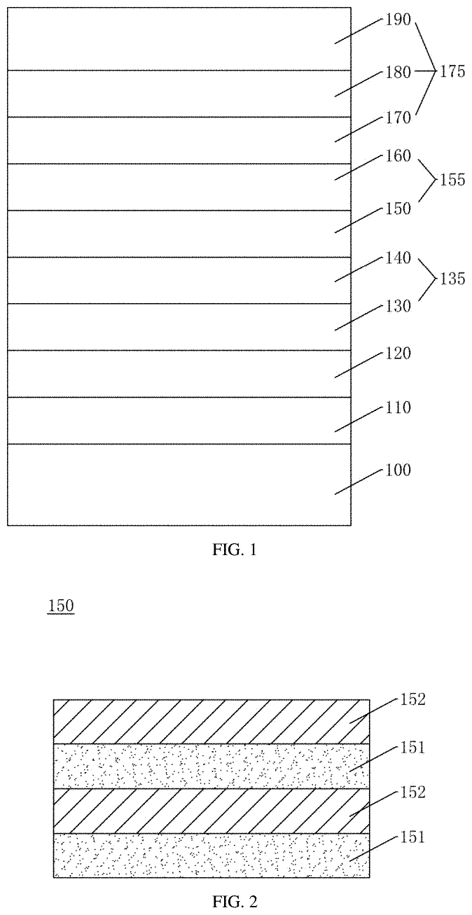

Referring to FIG. 1, an epitaxial structure is provided in implementations of the disclosure. The epitaxial structure includes an N-type semiconductor layer 135, a multiple quantum well (MQW) active layer 155, and a P-type semiconductor layer 175 that are sequentially stacked in a growth direction.

The MQW active layer 155 includes a front MQW active layer 150 and a back MQW active layer 160 that are sequentially stacked in the growth direction.

In conjunction with FIG. 2, the front MQW active layer 150 includes at least two groups of first quantum barrier layers 152 and first quantum well layers 151 that are alternately stacked.

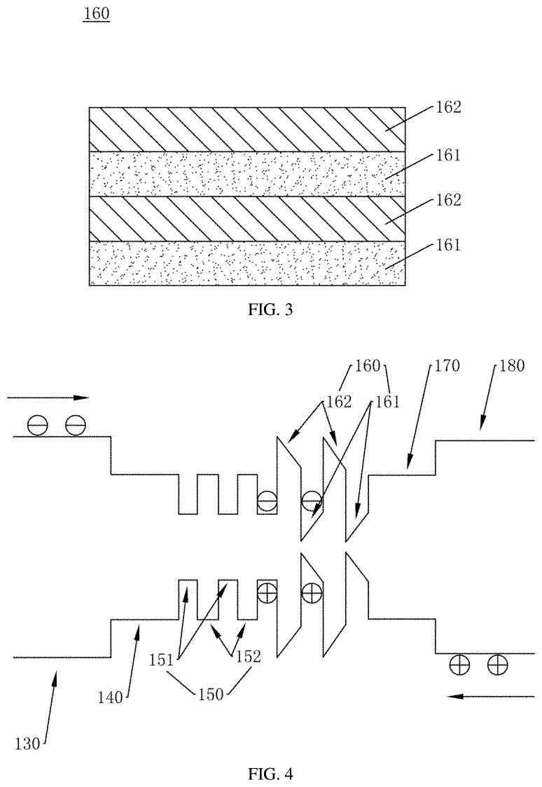

In conjunction with FIG. 3, the back MQW active layer 160 includes at least two groups of second quantum barrier layers 162 and second quantum well layers 161 that are alternately stacked.

A content of an Al component in each of the second quantum well layers 161 is gradually increased in the growth direction, and a content of a Ga component in each of the second quantum well layers 161 is gradually decreased in the growth direction.

Optionally, the epitaxial structure in the implementation is an AlGaInP red-light epitaxial structure. Specifically, referring to FIG. 1, the epitaxial structure further includes a gallium arsenide (GaAs) buffer layer 110 and an AlGaAs/AlAs distributed bragg reflection (DBR) layer 120 that are grown sequentially on a GaAs substrate 100. In other implementations, the epitaxial structure can also be other types of epitaxial structures.

The N-type semiconductor 135 is grown on the AlGaAs/AlAs DBR layer 120. The N-type semiconductor 135 includes an N—AlInP confinement layer 130 and an N—AlGaInP waveguide layer 140.

Referring to FIG. 2, in the front MQW active layer 150, each of the first quantum well layers 151 is an (Al_{A}Ga_{1-A})_{0.5}In_{0.5}P layer, where 0.2≤A≤0.3. Optionally, a thickness of each of the first quantum well layers 151 ranges from 3 nm to 6 nm. Further optionally, the thickness of each of the first quantum well layers 151 is 5 nm. Optionally, the number of the first quantum well layers 151 grown is 18.

Referring to FIG. 2, in the front MQW active layer 150, each of the first quantum barrier layers 152 is an (Al_{B}Ga_{1-B})_{0.5}In_{0.5}P layer, where 0.6≤B≤0.7. Optionally, a thickness of each of the first quantum barrier layers 152 ranges from 3 nm to 6 nm. Further optionally, the thickness of each of the first quantum barrier layers 152 is 5 nm. Optionally, the number of the first quantum barrier layers 152 grown is 17.

Referring to FIG. 3 and FIG. 4, in the back MQW active layer 160, each of the second quantum well layers 161 is an (Al_{C}Ga_{1-C})_{0.5}In_{0.5}P layer, where a value of C is gradually changed from 0.1 to 0.3 in the growth direction. A potential barrier of a well is increased, which can increase a residence time of an electron in a well, block the electron from overflowing from the back MQW active layer 160, and increase a recombination probability of the electron and a hole, thereby increasing light-emitting efficiency of an LED. Optionally, when the epitaxial structure is an AlGaInP red-light epitaxial structure, the LED is an AlGaInP LED. Optionally, a thickness of each of the second quantum well layers 161 ranges from 3 nm to 6 nm. Further optionally, the thickness of each of the second quantum well layers 161 is 5 nm. Optionally, the number of the second quantum well layers 161 grown is 5.

Referring to FIG. 3 and FIG. 4, in the back MQW active layer 160, a content of an Al component in each of the second quantum barrier layers 162 is gradually decreased in the growth direction, and a content of a Ga component in each of the second quantum barrier layers 162 is gradually increased in the growth direction. Specifically, each of the second quantum barrier layers 162 is an (Al_{D}Ga_{1-D})_{0.5}In_{0.5}P layer, where a value of D is gradually changed from 0.8 to 0.6 in the growth direction. A potential barrier of a barrier is changed from high to low, which can block a fast-moving electron, block the electron from overflowing from the back MQW active layer 160, and increase a recombination probability of the electron and a hole, thereby increasing light-emitting efficiency of an LED. Optionally, a thickness of each of the second quantum barrier layers 162 ranges from 3 nm to 6 nm. Further optionally, the thickness of each of the second quantum barrier layers 162 is 5 nm. Optionally, the number of the second quantum barrier layers 162 grown is 5.

By alternately growing the second quantum well layers 161 and the second quantum barrier layers 162, the second quantum well layers 161 and the second quantum barrier layers 162 interact with each other, which can jointly prevent an electron from overflowing from the back MQW active layer 160, and increase a recombination probability of the electron and a hole, thereby increasing light-emitting efficiency of an LED, and increasing light-emitting brightness.

The P-type semiconductor layer 175 includes a P—AlGaInP waveguide layer 170, a P—AlInP confinement layer 180, and a P—GaP current spreading layer 190.

In the implementation, by growing the front MQW active layer 150 and the back MQW active layer 160 and setting the back MQW active layer 160 to include at least two groups of the second quantum barrier layers 162 and the second quantum well layers 161 that are alternately stacked, where the content of the Al component in each of the second quantum well 161 layers is gradually increased in the growth direction, and the content of the Ga component in each of the second quantum well layers 161 is gradually decreased in the growth direction, a potential barrier of each of the second quantum well layers 161 is increased, which can increase a residence time of an electron in a well, block the electron from overflowing from the back MQW active layer 160, and increase a recombination probability of the electron and a hole, thereby increasing light-emitting efficiency of an LED, and increasing light-emitting brightness.

In an implementation, referring to FIG. 1, FIG. 2, and FIG. 4, the eighteen first quantum well layers 151 and the seventeen first quantum barrier layers 152 are alternately grown, and a first layer of the first quantum well layers 151 is grown on the N—AlGaInP waveguide layer 140.

In an implementation, referring to FIG. 1, FIG. 3, and FIG. 4, the five second quantum barrier layers 162 and the five second quantum well layers 161 are alternately grown, and a first layer of the second quantum barrier layers 162 is grown on an 18^{th} layer of the first quantum well layers 151.

Referring to FIG. 1 to FIG. 4, growth procedures of the front MQW active layer 150 and the back MQW active layer 160 of the epitaxial structure in an implementation are as follows.

The eighteen first quantum well layers 151 and the seventeen first quantum barrier layers 152 are alternately grown on the N—AlGaInP waveguide layer 140. That is, the first layer of the first quantum well layers 151 is grown on the N—AlGaInP waveguide layer 140, a first layer of the first quantum barrier layers 152 is grown on the first layer of the first quantum well layers 151, and the first quantum well layers 151 and the first quantum barrier layers 152 are alternately grown until growth of the eighteen first quantum well layers 151 and the seventeen first quantum barrier layers 152 is completed, where a layer farthest from the N—AlGaInP waveguide layer 140 is the 18^{th} layer of the first quantum well layers 151. The growth of the front MQW active layer 150 is completed.

Thereafter, the five second quantum well layers 161 and the five second quantum barrier layers 162 are alternately grown on the 18^{th} layer of the first quantum well layers 151. That is, the first layer of the second quantum barrier layers 162 is grown on the 18^{th} layer of the first quantum well layers 151, and the second quantum well layers 161 and the second quantum barrier layers 162 are alternately grown until growth of the five second quantum well layers 161 and the five second quantum barrier layers 162 is completed, where a layer farthest from the N—AlGaInP waveguide layer 140 is a 5^{th} layer of the second quantum well layers 161. The growth of the back MQW active layer 160 is completed.

Thereafter, the P—AlGaInP waveguide layer 170 is grown on the 5^{th} layer of the second quantum well layers 161.

In an implementation, referring to FIG. 1 and FIG. 4, the GaAs buffer layer 110 has a thickness ranging from 0.4 μm to 0.6 μm, the AlGaAs/AlAs DBR layer 120 has a thickness ranging from 2.0 μm to 4.0 μm, the N—AlInP confinement layer 130 has a thickness ranging from 0.25 μm to 0.45 μm, the N—AlGaInP waveguide layer 140 has a thickness ranging from 0.06 μm to 0.1 μm, the P-AlGaInP waveguide layer 170 has a thickness ranging from 0.07 μm to 0.1 μm, the P—AlInP confinement layer 180 has a thickness ranging from 0.3 μm to 1 μm, and the P—GaP current spreading layer 190 has a thickness ranging from 5 μm to 6 μm.

Referring to FIG. 1, based on the same inventive concept, a manufacturing method of an epitaxial structure is further provided in implementations of the disclosure. The manufacturing method of an epitaxial structure includes the following. A GaAs substrate 100 is provided. A GaAs buffer layer 110, an AlGaAs/AlAs DBR layer 120, an N—AlInP confinement layer 130, an N—AlGaInP waveguide layer 140, a front MQW active layer 150, a back MQW active layer 160, a P—AlGaInP waveguide layer 170, a P—AlInP confinement layer 180, and a P-GaP current spreading layer 190 are grown sequentially on the GaAs substrate 100.

The epitaxial structure in the implementation can be grown with a metal-organic chemical vapor deposition (MOCVD) process. Specifically, the MOCVD process is to grow structures of various functional layers by introducing various raw materials and gases into a reaction chamber and controlling reaction conditions such as a growth temperature or a growth pressure.

At first, the GaAs substrate 100 is purged with hydrogen (H₂) to remove impurities on a surface of the GaAs substrate 100, a temperature of the reaction chamber is set to be kept between 650° C. and 750° C., and water vapor in the reaction chamber is removed through high-temperature treatment. A thickness of the GaAs substrate 100 is not limited.

The GaAs buffer layer 110 is grown on the GaAs substrate 100. The GaAs buffer layer 110 grown has a thickness ranging from 0.4 μm to 0.6 μm.

The AlGaAs/AlAs DBR layer 120 is grown on the GaAs buffer layer 110. The AlGaAs/AlAs DBR layer 120 includes first reflectivity layers AlAs (not shown in the figure) and second reflectivity layers AlGaAs (not shown in the figure) that are alternately grown. Each of the first reflectivity layers has a reflectivity less than each of the second reflectivity layers. The growth starts with the first reflectivity layer and ends with the first reflectivity layer. The AlGaAs/AlAs DBR layer 120 grown has a thickness ranging from 2.0 μm to 4.0 μm.

The N—AlInP confinement layer 130 is grown on the AlGaAs/AlAs DBR layer 120. The N—AlInP confinement layer 130 grown has a thickness ranging from 0.25 μm to 0.45 μm.

The N—AlGaInP waveguide layer 140 is grown on the N—AlInP confinement layer 130. The N—AlGaInP waveguide layer 140 grown has a thickness ranging from 0.06 μm to 0.1 μm.

The front MQW active layer 150 is grown on the N—AlGaInP waveguide layer 140. The front MQW active layer 150 grown has a thickness of 175 nm and a growth pressure ranging from 45 millibars (mbar) to 65 mbar.

The back MQW active layer 160 is grown on the front MQW active layer 150. The back MQW active layer 160 grown has a thickness of 50 nm and a growth pressure ranging from 45 mbar to 65 mbar.

The P—AlGaInP waveguide layer 170 is grown on the back MQW active layer 160. The P—AlGaInP waveguide layer 170 grown has a thickness ranging from 0.07 μm to 0.1 μm.

The P—AlInP confinement layer 180 is grown on the P—AlGaInP waveguide layer 170. The P—AlInP confinement layer 180 grown has a thickness ranging from 0.3 μm to 1 μm.

The P—GaP current spreading layer 190 is grown on the P—AlInP confinement layer 180. The P—GaP current spreading layer 190 grown has a thickness ranging from 5 μm to 6 μm.

In conjunction with FIG.1, FIG. 2, and FIG. 4, growing the front MQW active layer 150 includes growing multiple first quantum barrier layers 152 and multiple first quantum well layers 151 that are alternately stacked.

In conjunction with FIG.1, FIG. 3, and FIG. 4, growing the back MQW active layer 160 includes growing multiple second quantum barrier layers 162 and multiple second quantum well layers 161 that are alternately stacked.

A content of an Al component in each of the multiple second quantum well layers 161 is gradually increased in a growth direction, and a content of a Ga component in each of the multiple second quantum well layers 161 is gradually decreased in the growth direction.

In the implementation, by growing the front MQW active layer 150 and the back MQW active layer 160 and setting the back MQW active layer 160 to include at least two groups of the second quantum barrier layers 162 and the second quantum well layers 161 that are alternately stacked, where the content of the Al component in each of the second quantum well 161 layers is gradually increased in the growth direction, and the content of the Ga component in each of the second quantum well layers 161 is gradually decreased in the growth direction, a potential barrier of each of the second quantum well layers 161 is increased, which can increase a residence time of an electron in a well, block the electron from overflowing from the back MQW active layer 160, and increase a recombination probability of the electron and a hole, thereby increasing light-emitting efficiency of an LED, and increasing light-emitting brightness.

When a well and a barrier of the back MQW active layer 160 are grown in the reaction chamber with the MOCVD process, an amount of Al can be controlled by controlling an amount of trimethylaluminium (TMA1) introduced into the reaction chamber through a mass flow controller (MFC). Specifically, when growing the second quantum well layers 161, a source value of the TMA1 is controlled to be changed linearly in a fixed time, so that the value of C is ensured to be uniformly changed from 0.1 to 0.3. Similarly, when growing the second quantum barrier layers 162, a source value of the TMA1 is controlled to be changed linearly in a fixed time, so that the value of D is ensured to be uniformly changed from 0.8 to 0.6. As a result, the well and the barrier can be sequentially alternately grown. When growing the back MQW active layer, it is required to strictly control a growth temperature, a growth pressure, well-barrier switching, and an introduced amount of required MO sources to ensure better growth of gradually changed barrier and well.

By alternately growing the second quantum well layers 161 and the second quantum barrier layers 162, the second quantum well layers 161 and the second quantum barrier layers 162 interact with each other, which can jointly prevent an electron from overflowing from the back MQW active layer 160, and increase a recombination probability of the electron and a hole, thereby increasing light-emitting efficiency of an LED, and increasing light-emitting brightness.

When growing the front MQW active layer 150, proportions of the Al component and the Ga component therein are controlled to be unchanged. Specifically, an amount of Al and an amount of Ga can be controlled by controlling an amount of TMA1 and an amount of trimethylgallium (TMGa) introduced into the reaction chamber through the MFC, such that each of the value of A and the value of B is a fixed value within the range.

Referring to FIG. 1, based on the same inventive concept, an LED device is further provided in implementations of the disclosure. The LED device includes an N electrode, a P electrode, and the epitaxial structure of any of the foregoing implementations, where the N electrode is configured to be electrically coupled with the N-type semiconductor layer 135, and the P electrode is configured to be electrically coupled with the P-type semiconductor layer 175.

With the LED device in implementations of the disclosure, by growing the front MQW active layer 150 and the back MQW active layer 160 and setting the back MQW active layer 160 to include at least two groups of the second quantum barrier layers 162 and the second quantum well layers 161 that are alternately stacked, where the content of the Al component in each of the second quantum well 161 layers is gradually increased in the growth direction, and the content of the Ga component in each of the second quantum well layers 161 is gradually decreased in the growth direction, a potential barrier of each of the second quantum well layers 161 is changed from low to high, which can increase a residence time of an electron in a well, block the electron from overflowing from the back MQW active layer 160, and increase a recombination probability of the electron and a hole, thereby increasing light-emitting efficiency of an LED, and increasing light-emitting brightness.

It is to be understood that application of the disclosure is not to be limited to the above implementations. Those of ordinary skill in the art can make improvements or changes based on the above description, and all these improvements and changes should fall within the protection scope of the appended claims of this disclosure.

What is claimed is:

1. An epitaxial structure, comprising an N-type semiconductor layer, a multiple quantum well (MQW) active layer, and a P-type semiconductor layer that are sequentially stacked in a growth direction, wherein
the MQW active layer comprises a front MQW active layer and a back MQW active layer that are sequentially stacked in the growth direction;
the front MQW active layer comprises at least two groups of first quantum barrier layers and first quantum well layers that are alternately stacked;
the back MQW active layer comprises at least two groups of second quantum barrier layers and second quantum well layers that are alternately stacked; and
a content of an aluminum (Al) component in each of the second quantum well layers is gradually increased in the growth direction, and a content of a gallium (Ga) component in each of the second quantum well layers is gradually decreased in the growth direction.

2. The epitaxial structure of claim 1, wherein
each of the second quantum well layers is an (aluminumcgallium_{1-C})_{0.5}indium_{0.5}phosphorus ((Al_{C}Ga_{1-C})_{0.5}In_{0.5}P) layer, wherein a value of C is gradually changed from 0.1 to 0.3 in the growth direction.

3. The epitaxial structure of claim 1, wherein
a content of an Al component in each of the second quantum barrier layers is gradually decreased in the growth direction; and
a content of a Ga component in each of the second quantum barrier layers is gradually increased in the growth direction.

4. The epitaxial structure of claim 3, wherein
each of the second quantum barrier layers is an (Al_{D}Ga_{1-D})_{0.5}In_{0.5}P layer; wherein a value of D is gradually changed from 0.8 to 0.6 in the growth direction.

5. The epitaxial structure of claim 1, wherein
each of the first quantum well layers is an (Al_{A}Ga_{1-A})_{0.5}In_{0.5}P layer, wherein 0.2≤A≤0.3; and
each of the first quantum barrier layers is an (Al_{B}Ga_{1-B})_{0.5}In_{0.5}P layer, wherein 0.6≤B≤0.7.

6. The epitaxial structure of claim 1, wherein a thickness of each of the first quantum barrier layers, the first quantum well layers, the second quantum barrier layers, and the second quantum well layers ranges from 3 nm to 6 nm.

7. The epitaxial structure of claim 1, wherein
the N-type semiconductor layer comprises an N—AlInP confinement layer and an N—AlGaInP waveguide layer that are sequentially stacked in the growth direction; and
the P-type semiconductor layer comprises a P—AlGaInP waveguide layer, a P—AlInP confinement layer, and a P—GaP current spreading layer that are sequentially stacked in the growth direction.

8. The epitaxial structure of claim 7, further comprising:
a gallium arsenide (GaAs) buffer layer and an AlGaAs/AlAs distributed bragg reflection (DBR) layer that are sequentially stacked in the growth direction, wherein the GaAs buffer layer and the AlGaAs/AlAs DBR layer are disposed on one side of the N-type semiconductor layer away from the MQW active layer.

9. The epitaxial structure of claim 8, wherein
the GaAs buffer layer has a thickness ranging from 0.4 μm to 0.6 μm;
the AlGaAs/AlAs DBR layer has a thickness ranging from 2.0 μm to 4.0 μm;
the N—AlInP confinement layer has a thickness ranging from 0.25 μm to 0.45 μm;
the N—AlGaInP waveguide layer has a thickness ranging from 0.06 μm to 0.1 μm;
the P—AlGaInP waveguide layer has a thickness ranging from 0.07 μm to 0.1 μm;
the P—AlInP confinement layer has a thickness ranging from 0.3 μm to 1 μm; and
the P—GaP current spreading layer has a thickness ranging from 5 μm to 6 μm.

10. A manufacturing method of an epitaxial structure, comprising:
providing a gallium arsenide (GaAs) substrate;
growing a GaAs buffer layer, an aluminum gallium arsenide/aluminum arsenide (AlGaAs/AlAs) distributed bragg reflection (DBR) layer, an N-aluminum indium phosphorus (N—AlInP) confinement layer, an N—AlGaInP waveguide layer, a front multiple quantum well (MQW) active layer, a back MQW active layer, a P—AlGaInP waveguide layer, a P—AlInP confinement layer, and a P—GaP current spreading layer sequentially on the GaAs substrate, wherein
the front MQW active layer comprises a plurality of first quantum barrier layers and a plurality of first quantum well layers that are alternately stacked;
the back MQW active layer comprises a plurality of second quantum barrier layers and a plurality of second quantum well layers that are alternately stacked;
a content of an Al component in each of the plurality of second quantum well layers is gradually increased in a growth direction, and a content of a Ga component in each of the plurality of second quantum well layers is gradually decreased in the growth direction.

11. The manufacturing method of an epitaxial structure of claim 10, wherein
each of the plurality of second quantum well layers is an (Al_{C}Ga_{1-C})_{0.5}In_{0.5}P layer; wherein a value of C is gradually changed from 0.1 to 0.3 in the growth direction.

12. The manufacturing method of an epitaxial structure of claim 10, wherein
a content of an Al component in each of the plurality of second quantum barrier layers is gradually decreased in the growth direction; and
a content of a Ga component in each of the plurality of second quantum barrier layers is gradually increased in the growth direction.

13. The manufacturing method of an epitaxial structure of claim 12, wherein
each of the plurality of second quantum barrier layers is an (Al_{D}Ga_{1-D})_{0.5}In_{0.5}P layer; wherein a value of D is gradually changed from 0.8 to 0.6 in the growth direction.

14. The manufacturing method of an epitaxial structure of claim 10, wherein
each of the plurality of first quantum well layers is an (Al_{A}Ga_{1-A})_{0.5}In_{0.5}P layer, wherein 0.2≤A≤0.3; and
each of the plurality of first quantum barrier layers is an (Al_{B}Ga_{1-B})_{0.5}In_{0.5}P layer, wherein 0.6≤A≤0.7.

15. The manufacturing method of an epitaxial structure of claim 10, wherein a thickness of each of the plurality of first quantum barrier layers, the plurality of first quantum well layers, the plurality of second quantum barrier layers, and the plurality of second quantum well layers ranges from 3 nm to 6 nm.

16. The manufacturing method of an epitaxial structure of claim 10, wherein
the GaAs buffer layer has a thickness ranging from 0.4 μm to 0.6 μm;
the AlGaAs/AlAs DBR layer has a thickness ranging from 2.0 μm to 4.0 μm;
the N—AlInP confinement layer has a thickness ranging from 0.25 μm to 0.45 μm;
the N—AlGaInP waveguide layer has a thickness ranging from 0.06 μm to 0.1 μm;
the P—AlGaInP waveguide layer has a thickness ranging from 0.07 μm to 0.1 μm;
the P—AlInP confinement layer has a thickness ranging from 0.3 μm to 1 μm; and
the P—GaP current spreading layer has a thickness ranging from 5 μm to 6 μm.

17. A light-emitting diode (LED) device, comprising an N electrode, a P electrode, and an epitaxial structure comprising an N-type semiconductor layer, a multiple quantum well (MQW) active layer, and a P-type semiconductor layer that are sequentially stacked in a growth direction, wherein
the MQW active layer comprises a front MQW active layer and a back MQW active layer that are sequentially stacked in the growth direction;
the front MQW active layer comprises at least two groups of first quantum barrier layers and first quantum well layers that are alternately stacked;
the back MQW active layer comprises at least two groups of second quantum barrier layers and second quantum well layers that are alternately stacked;
a content of an aluminum (Al) component in each of the second quantum well layers is gradually increased in the growth direction, and a content of a gallium (Ga) component in each of the second quantum well layers is gradually decreased in the growth direction; and
the N electrode is configured to be electrically coupled with the N-type semiconductor layer, and the P electrode is configured to be electrically coupled with the P-type semiconductor layer.

18. The LED device of claim 17, wherein
each of the second quantum well layers is an (aluminum_{C}gallium_{1-C})_{0.5}indium_{0.5}phosphorus ((Al_{C}Ga_{1-C})_{0.5}In_{0.5}P) layer, wherein a value of C is gradually changed from 0.1 to 0.3 in the growth direction.

19. The LED device of claim 17, wherein
a content of an Al component in each of the second quantum barrier layers is gradually decreased in the growth direction; and
a content of a Ga component in each of the second quantum barrier layers is gradually increased in the growth direction.

20. The LED device of claim 19, wherein
each of the second quantum barrier layers is an (Al_{D}Ga_{1-D})_{0.5}In_{0.5}P layer; wherein a value of D is gradually changed from 0.8 to 0.6 in the growth direction.
